(19) United States
(12) Patent Application Publication
(10) Pub. No.: US 2015/0262670 A1
(43) Pub. Date: Sep. 17, 2015

(54) NONVOLATILE SEMICONDUCTOR MEMORY DEVICE

(71) Applicant: KABUSHIKI KAISHA TOSHIBA, Tokyo (JP)

(72) Inventor: Koji HOSONO, Kanagawa Fujisawa (JP)

(21) Appl. No.: 14/470,783

(22) Filed: Aug. 27, 2014

(30) Foreign Application Priority Data
Mar. 14, 2014 (JP) 2014-052687

(51) Int. Cl. G11C 16/04; G11C 16/10

(52) U.S. Cl. CPC G11C 16/0483; G11C 16/10

(57) ABSTRACT

A nonvolatile semiconductor memory device includes a plurality of memory cells electrically connected in series between first and second select transistors and stacked above a semiconductor substrate, a voltage generation circuit, and a controller that controls the voltage generation circuit to apply a write voltage to at least one of the memory cells before a write operation is performed on the first select transistor and, during the write operation on the first select transistor, apply a first voltage to gates of the memory cells, a second voltage that is higher than the first voltage to a gate of the second select transistor, and a third voltage that is higher than the second voltage to a gate of the first select transistor.

### CROSS-REFERENCE TO RELATED APPLICATION

This application is based upon and claims the benefit of priority from Japanese Patent Application No. 2014-052687, filed Mar. 14, 2014, the entire contents of which are incorporated herein by reference.

### FIELD

Embodiments described herein relate generally to a nonvolatile semiconductor memory device capable of reducing write disturbance.

### BACKGROUND

Recently, a stacked semiconductor memory (BiCS: Bit Cost Scalable Flash Memory) in which memory cells are stacked has been developed. With this BiCS, a high-capacity semiconductor memory may be realized at a low cost.

### DESCRIPTION OF THE DRAWINGS

FIG. 1 is a diagram illustrating an overall configuration example of a nonvolatile semiconductor memory device according to a first embodiment.

FIG. 2 is a plan view illustrating a memory cell array according to the first embodiment.

FIG. 3 is a cross-sectional view of a sub-block according to the first embodiment.

FIG. 4 is an equivalent circuit diagram illustrating the sub-block according to the first embodiment.

FIGS. 5A to 5D are flowcharts illustrating a write operation of a select transistor according to the first embodiment.

FIG. 6 is a timing diagram illustrating the write operation of the select transistor according to the first embodiment.

FIG. 7 is a timing diagram illustrating the write operation of the select transistor according to the first embodiment.

FIG. 8 is a conceptual diagram illustrating the write operation of the select transistor according to the first embodiment.

FIG. 9 is a flowchart illustrating a write operation of a select transistor according to a second embodiment.

FIG. 10 is a timing diagram illustrating the write operation of the select transistor according to the second embodiment.

FIG. 11 is a conceptual diagram illustrating a read operation of the select transistor according to the second embodiment.

FIG. 12 is a plan view illustrating a memory cell array according to a third embodiment.

FIG. 13 is a cross-sectional view illustrating the memory cell according to the third embodiment.

FIG. 14 is an enlarged view illustrating the memory cell according to the third embodiment.

FIG. 15 is an equivalent circuit diagram illustrating the memory cell according to the third embodiment.

FIG. 16 is a timing diagram illustrating a write operation of a select transistor according to the third embodiment.

FIG. 17 is a conceptual diagram illustrating the write operation of the select transistor according to the third embodiment.

FIG. 18 is a timing diagram illustrating the write operation of the select transistor according to the third embodiment.

### DETAILED DESCRIPTION

The present embodiment now will be described more fully hereinafter with reference to the accompanying drawings, in which various embodiments are shown. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, may therefore, encompass both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” can, therefore, encompass both an orientation of above and below.

Embodiments are described herein with reference to cross sections and perspective illustrations that are schematic illustrations of embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

A nonvolatile semiconductor memory device capable of improving operational capability is provided.

According to one embodiment, there is provided a nonvolatile semiconductor memory device including a plurality of memory cells electrically connected in series between first and second select transistors and stacked above a semiconductor substrate, a voltage generation circuit, and a controller that controls the voltage generation circuit to apply a write voltage to at least one of the memory cells before a write operation is performed on the first select transistor and, during the write operation on the first select transistor, apply a first voltage to gates of the memory cells, a second voltage that is higher than the first voltage to a gate of the second select transistor, and a third voltage that is higher than the second voltage to a gate of the first select transistor.

Hereinafter, embodiments will be described with reference to the accompanying drawings. In this description, in all the drawings, like components are represented by line reference numerals. However, the drawings are schematic, and it should be noted that a relationship between a thickness and a planar dimension, a ratio of the thickness of each layer, and the like may be different from the actual ones. Accordingly, a specific thickness or dimension should be determined based on the following description. Moreover, it should be recognized that a dimensional relationship and a ratio of a portion vary depending on the drawings.

### First Embodiment

### Overall Configuration Example

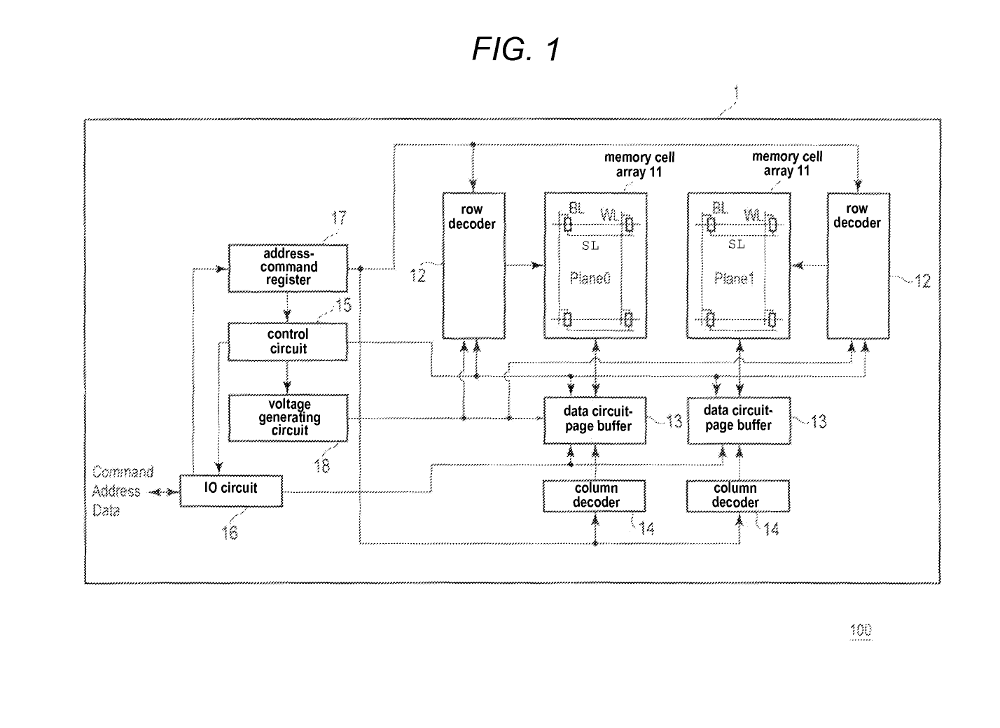

An overall configuration of a nonvolatile semiconductor memory device according to a first embodiment will be described using FIG. 1. FIG. 1 is a block diagram illustrating the nonvolatile semiconductor memory device according to the first embodiment.

As illustrated in FIG. 1, a nonvolatile semiconductor memory device 1 according to the first embodiment includes a memory cell array 11, a row decoder 12, a data circuit-page buffer 13, a column decoder 14, a control circuit 15, an input-output circuit 16, an address-command register 17, and an internal voltage generating circuit 18.

### 1. Memory Cell Array 11

As illustrated in FIG. 1, the memory cell array 11 includes, for example, a plane P0 and a plane P1 (in FIG. 1, indicated by Plane0 and Plane1). These planes P0 and P1 include a plurality of memory strings MS. Bit lines BL, word lines WL, and source lines SL are electrically connected to these memory strings MS.

As will be described below, the memory string MS includes a plurality of memory cells MC that are connected in series to each other, and the above-described word lines WL are connected to a control gate CG included in the memory cell MC.

Here, although the case where the nonvolatile semiconductor memory device includes the planes P0 and P1 is described as an example, the number of planes P included in the memory cell array 11 is not limited. When the planes P0 and P1 do not need to be distinguished from each other, these planes will be simply referred to as the planes P.

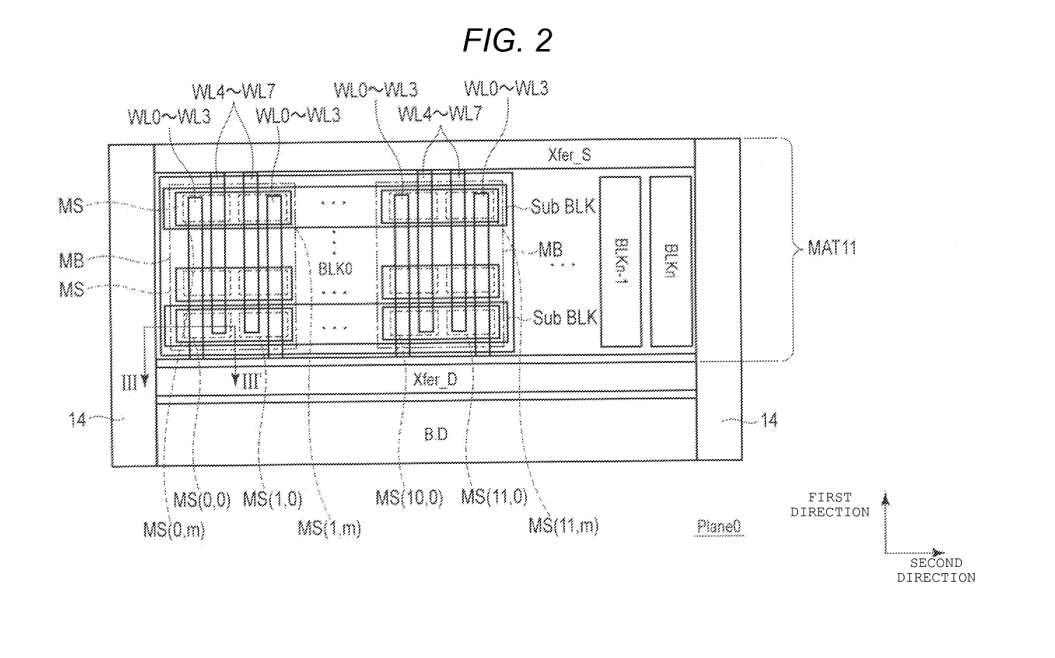

Hereinafter, the detailed configuration of the planes P will be described using FIG. 2.

### 1.1 Plan View of Plane0

Next, for example, a plan view (top view) of Plane0 will be described using FIG. 2. Since Plane 1 has the same configuration as that of Plane0, the description thereof will not be repeated.

In addition, for convenience of the description, the row decoder 12 (in the drawings, indicated by Xfer_S and Xfer_D; a block decoder (B.D)) and a column decoder COL (in the drawings, indicated by 14) are illustrated in addition to the plan view of Plane0.

Plane0 is formed of a group of the memory cells MC. Specifically, as illustrated in FIG. 2, for example, the memory string MS (in FIG. 2, indicated by MS) is formed of 48 memory cells MC connected to word lines WL0 to WL47.

In addition, a sub-block SB (in the drawings, indicated by Sub BLK) is formed of, for example, a group of the memory strings MS (for example 12 memory strings MS).

In this case, hereinafter, the memory strings MS connected to a bit line BL0 (not illustrated) in a second direction will be represented by memory strings MS (0, 0), (1,0), . . . , (10,0), and (11,0). In addition, hereinafter, the memory strings MS connected to a bit line BLm will be represented by memory strings MS(0,m), (1,m), . . . , (10,m), and (11,m).

In addition, groups that are disposed in a word line WL direction and are formed of, for example, a pair of memory strings MS0 and MS1, a pair of memory strings MS2 and MS3, . . . , and a pair of memory strings MS10 and MS11 will be referred to as memory blocks MB.

When the sub-block SB is formed of 12 memory strings MS, 6 memory blocks MB are formed in the block BLK.

In addition, for example, a group of the memory strings MS0 which are connected to the bit lines BL0, B11, BL2, . . . , and BLm will be referred to as a memory string unit MU. Since the same shall be applied to the memory strings MS1 to MS11, the description thereof will not be repeated.

In Plane0, the word lines WL0 to WL23 (hereinafter, referred to as a first signal line group) and the word lines WL24 to WL47 (hereinafter, referred to as a second signal line group) are formed in a first direction in a comb-teeth shape. In addition, a semiconductor layer SC described below is formed in a depth direction of the drawing so as to penetrate each memory string MS. The memory cells MC are formed at intersections between the word lines WL and the semiconductor layers SC.

As illustrated in the drawing, Xfer_D and Xfer_S are disposed in a second direction. Ends of the word lines WL0 to WL23 are connected to Xfer_D, and ends of the word lines WL24 to WL47 are connected to Xfer_S.

As described above, Xfer_D and Xfer_S are formed of a plurality of MOS transistors and select any of the memory strings MS in the block BLK. Specifically, Xfer_D and Xfer_S may select memory strings MS of a read target and a write target based on the decoding result from the block decoder BD.

The column decoder COL selects the bit lines BL (not illustrated).

### 1.2 Cross-Sectional View of Sub-Block SB

### 1.2.1 Regarding Memory Strings MS0 to MS5

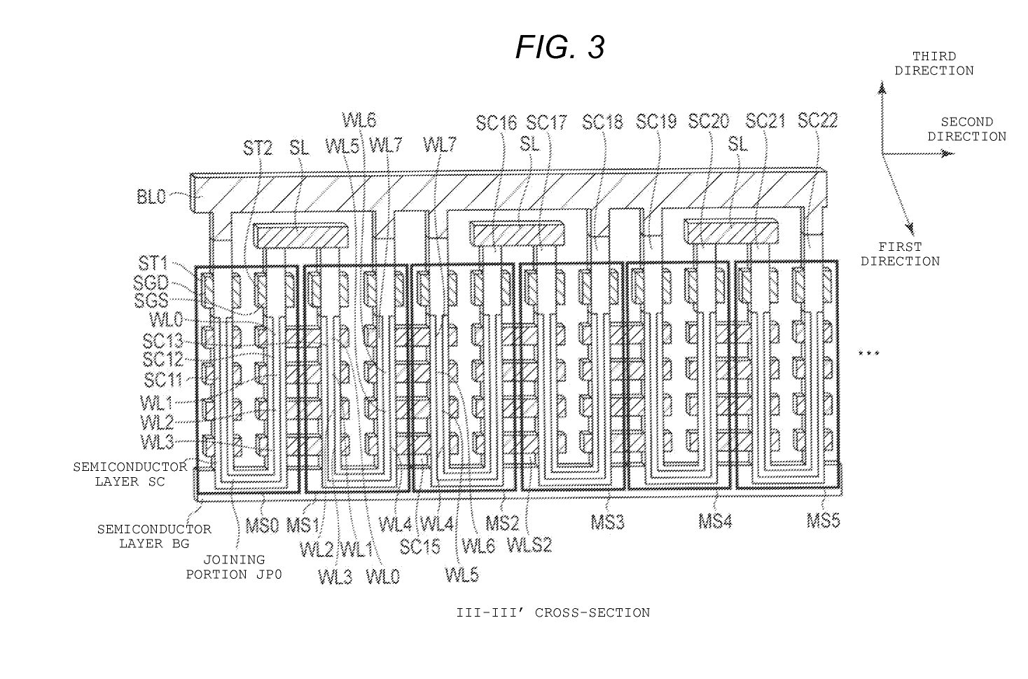

FIG. 3 is a cross-sectional view taken along line III-III′ of FIG. 2.

As illustrated in FIG. 3, the memory strings MS0 to MS5 (thick line) are provided along the cross-sectional direction. Here, for example, the word lines WL0 to WL7 are formed in each of the memory strings MS0 to MS5.

In each of the memory strings MS, columnar semiconductor layers SC11 and SC12 are formed on a semiconductor layer BG toward a third direction perpendicular to the first and the second directions. Hereinafter, when the semiconductor layers SC11 and SC12 do not need to be distinguished from each other, the semiconductor layers will be simply referred to as the semiconductor layers SC.

Next, the semiconductor layers SC adjacent to each other along the first direction are joined to each other through a joining portion JP provided inside the semiconductor layer BG. For example, the semiconductor layers SC11 and SC12 are joined to each other through a joining portion JP0 provided inside the semiconductor layer BG. With such a configuration, a U-shaped memory string MS0 is formed.

Since other pairs including a pair of semiconductor layers SC13 and SC14, . . . , and a pair of semiconductor layers SC21 and SC22 have the same configuration, the description thereof will not be repeated.

In addition, a plurality of polysilicon layers which are formed along the third direction are provided inside each of the memory strings MS. Some of the polysilicon layers function as the word lines WL, and the other polysilicon layers function as select signal lines SGS and SGD.

The select signal lines SGS and SGD are provided at positions between which the word lines WL are interposed. That is, as illustrated in FIG. 3, when the number of word lines WL is, for example, 4, the word lines WL3, WL2, WL1, and WL0 and the select signal line SGS are stacked on the semiconductor layer BG in this order from below while insulating films are interposed between the respective layers. Likewise, the word lines WL4, WL5, WL6, and WL7 and the select signal line SGD are stacked on the semiconductor layer BG in this order from below while insulating films are interposed between the respective layers.

Accordingly, a select transistor ST1, a memory cell MC7, a memory cell MC6, . . . , a memory cell MC1, a memory cell MC0, and a select transistor ST2 are provided at intersections of the semiconductor layers SC with the select signal lines SGS and SGD and the word lines WL.

Hereinafter, data stored in the memory cells MC0 to MC7 will be referred to as user data, and a region of the memory cells MC0 to MC7 in which these user data are stored will be referred to as a user data region.

Further, management data containing, for example control information is stored in the select transistors ST1 and ST2.

For example, one bit or two bits of data may be stored in the memory cell MC.

For example, when two bits of data may be stored in the memory cell MC, one of four values of the data may be stored therein.

The four values are level “E”, level “A”, level “B”, and level “C” in order from the lowest voltage. Level “E” is called an erase state and refers to a state where there are no charges on a charge storage layer. As charges accumulate on the charge storage layer, the voltage increases in the following order: level “A” to level “B” to level “C”.

The memory cell MC in the erase state corresponds to data “11”, the memory cell MC in a state where a threshold distribution is at level “A” corresponds to data “10”, the memory cell MC in a state where a threshold distribution is at level “B” corresponds to data “00”, and the memory cell MC in a state where a threshold distribution is at level “C” corresponds to data “01”.

For example, when one bit of data may be stored in the memory cell MC, one of two values of the data may be stored therein.

The two values are level “E” and level “C” in order from the lowest voltage. Level “E” is called an erase state and refers to a state where there are no charges on a charge storage layer. As charges accumulate on the charge storage layer, the voltage increases to level “C”.

The memory cell MC in the erase state corresponds to data “1”, and the memory cell MC in a state where a threshold distribution is at level “C” corresponds to data “0”.

These select signal lines SGS and SGD function as the select signal lines SGS and SGD for controlling the selection and non-selection of the memory strings MS.

In addition, to simplify the description, dummy word lines WLDD0, WLDD1, WLDS0, WLDS1, DDB, and DSB are not described.

In addition, in a timing diagram described below illustrating a write operation, these dummy word lines WL will also be collectively represented by “WLD”.

The configuration of the memory cell array 11 is disclosed in, for example, “Three dimensional stacked nonvolatile semiconductor memory”, U.S. patent application Ser. No. 12/407,403, filed on Mar. 19, 2009. In addition, the configuration of the memory cell array 11 is also disclosed in “Three dimensional stacked nonvolatile semiconductor memory”, U.S. patent application Ser. No. 12/406,524, filed on Mar. 18, 2009, “Non-volatile semiconductor storage device and method of manufacturing the same”, U.S. patent application Ser. No. 12/679,991, filed on Mar. 25, 2010, and “Semiconductor memory and method for manufacturing the same”, U.S. patent application Ser. No. 12/532,030, filed on Mar. 23, 2009. The entire contents of these patent applications are incorporated in this specification by reference.

### 1.2.2 Regarding Bit Line BL and Source Line SL

Tips of the semiconductor layers SC11 and SC14, the semiconductor layers SC15 and SC18, and the semiconductor layers SC19 and SC22 penetrate the select signal lines SGD and are commonly connected through the bit line BL0, respectively.

In addition, tips of the semiconductor layers SC12 and SC13, the semiconductor layers SC16 and SC17, and the semiconductor layers SC20 and SC21 penetrate the select signal lines SGS and are connected to the source lines SL, respectively. That is, for example, the semiconductor layers SC11 and SC12 and the semiconductor layers SC13 and SC14 which are adjacent to each other are commonly connected through the source lines SL.

### 1.2.3 Regarding Bit Lines BL1 to BLm−1

In the above description, the bit line BL0 is focused, and bit lines BL1 to BLm−1 have the same configuration as that of the bit line BL0.

That is, semiconductor layers SC connected to a bit line BLi (i: natural number, 1≦i≦m−1) will be referred to as “semiconductor layers SCi1 to SC(i+10)”. In this case, the above-described select signal line SGS, the word lines WL0 to WL7, and the select signal line SGD penetrate the semiconductor layers SCi1 to SC (i+10) such that a plurality of memory strings MS corresponding to the respective bit lines BLi are formed.

Regarding each memory string MS corresponding to the bit line BLi, the semiconductor layers SCi1 and Sci2 and semiconductor layers SCi3 and SCi4 which are adjacent to each other are commonly connected through the source line SL.

Here, the case where each memory string MS includes the memory cells MC0 to MC7 and the select transistors ST1 and ST2 is described as an example, but the number of memory cells MC is not limited. That is, the number of memory cells MC may be 16 or 32. Hereinafter, as necessary, the number of memory cells MC will also be referred to as “s (s: natural number)”.

In this way, Plane0 is formed by disposing the memory cells MC, which electrically store data, in a three-dimensional matrix shape. That is, the memory cells MC are disposed in a matrix shape not only in a stacking direction but in a horizontal direction perpendicular to the stacking direction. The plurality of memory cells MC which are disposed in the stacking direction as above are connected in series, and the memory string MS is formed by the plurality of memory cells MC connected in series to each other.

### 1.4 Circuit Diagram of Memory Cell Array 11

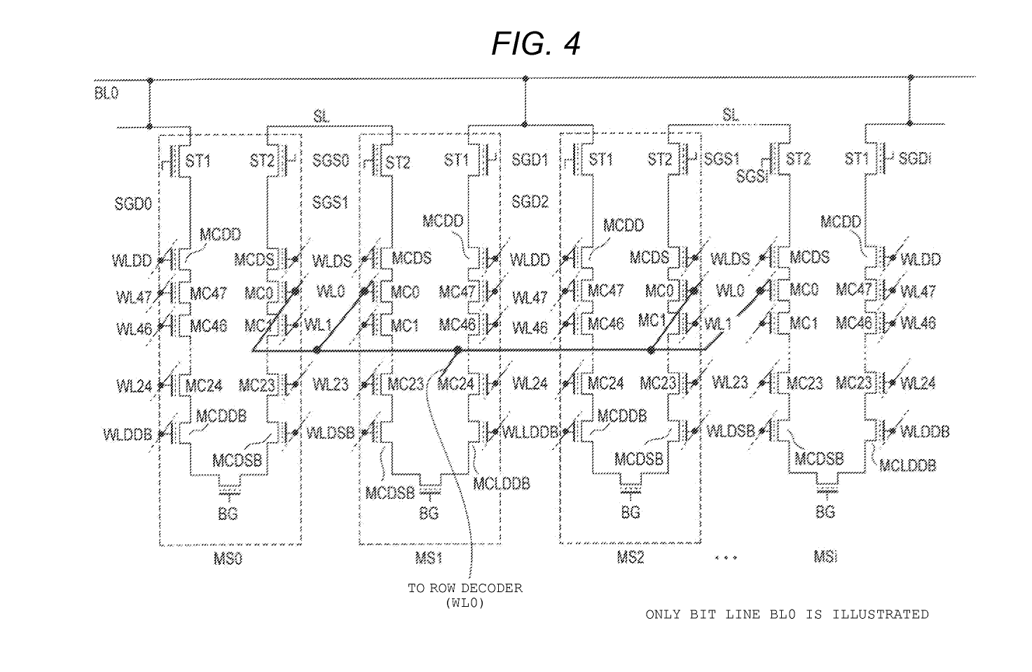

Next, an equivalent circuit of the above-described planes P will be described using FIG. 4. Here, the bit line BL0 is focused, and since the respective configurations of the memory strings MS0 to MSi (in the drawings, MS0 to MSi; i: positive real number) are the same, the memory string MS0 will be described in the following description. In addition, it is assumed that the number of memory cells MC included in each memory string MS is 48 (s=48).

### Regarding Memory String MS0

As illustrated in FIG. 4, the memory string MS0 includes the memory cells MC0 to MC47, the back gate transistor BG, dummy memory cells MCDD, MSDS, MCDDB, and MCDSB, and the select transistors ST1 and ST2. The dummy memory cell MCDD includes two dummy memory cells MCDD0 and MCDD1 but will be referred to as the dummy memory cell MCDD for convenience of description. The same is applied to the dummy memory cell MCDS.

As described above, the control gates CG of the memory cells MC0 to MC47 are connected to the corresponding word lines WL, respectively. That is, 48 word lines WL are connected to the memory string MS0.

The memory cells MC0 to MC23 are connected in series between the select transistor ST2 and the dummy memory cell MCDS; and a dummy bottom memory cell MCDSB and the back gate transistor BG.

A second end of a current path of the select transistor ST2 is connected to the source line SL, and a signal SGS_0 is supplied to a gate of the select transistor ST2.

A first end of a current path of the memory cell MC23 is connected to a first end of a current path of the back gate transistor BG, and a signal BG is supplied to a gate BG of the back gate transistor BG.

Further, a gate line DBS is connected to a gate of the dummy bottom memory cell MCDSB. In addition, a signal line WLDD is connected to a gate of a dummy memory cell MCDS.

In addition, the memory cells MC24 to MC47 are connected in series between the select transistor ST1 and the dummy memory cell MCDD; and a dummy bottom memory cell MCDDB and the back gate transistor BG.

A first end of a current path of the select transistor ST1 is connected to the bit line BL, and a signal SGD_0 is supplied to a gate of the select transistor ST1. A first end of a current path of the memory cell MC24 is connected to a second end of the current path of the back gate transistor BG.

Further, a signal line DD is connected to a gate of the dummy memory cell MCDD. In addition, a signal line DDB is connected to a gate of the dummy bottom memory cell MCDDB.

Next, the respective control gates CG of the memory cells MC0 to the memory cells MC47 which are provided inside the above-described memory strings MS0 to MSi are commonly connected. That is, for example, when the control gates CG of the memory cells MC0 provided inside the memory strings MS0 to MSi are focused, the control gates CG are commonly connected to the word line WL0.

The control gates CG of the memory cells MC1 to MC47 are commonly connected to the word lines WL1 to WL47, respectively.

All the memory cells MC0 which are provided inside the memory strings MS0 to MSi connected to other bit lines BL_1 to BL_m (not illustrated) are also commonly connected to the word line WL0.

In this way, the common connection ranges of the word lines WL are determined based on, for example, the specification of a nonvolatile semiconductor memory device, the size and the interconnection of the memory cells MC, and the size of the transistors. For example, when it is assumed that the page length (page is the unit of data access) corresponding to a direction in which the bit lines BL are disposed is 8 KB, the length of the memory string MS is 16 memory cells connected in series to each other, the common range between the memory strings MS in a direction moving along the bit lines BL is 4 strings, and the data memory capacity of each memory cell MC is 2 bit/cell, the memory capacity in the memory string MS which is common to the word lines WL is 1 MB (=8 KB×16×4×2). Here, this range will be referred to as a block BLK.

This nonvolatile semiconductor memory device performs a read operation and a write operation in units of the above-described page length but performs an erase operation in units of the above-described block BLK. The size of the above-described block BLK is merely exemplary and is not particularly limited.

### 2. Row Decoder 12

Referring to FIG. 1 again, the row decoder 12 (hereinafter, also referred to as “block decoder 12”) will be described. The row decoder 12 decodes a block address signal and the like input from the address-command register 17 and selects a desired word line WL according to the decoding result.

A voltage generated from the internal voltage generating circuit 18 is applied to the selected word line WL.

### 3. Data Circuit-Page Buffer 13

The data circuit-page buffer 13 includes a sense amplifier SA and a data cache DC which are not illustrated. That is, using the sense amplifier SA and the data cache DC, the data circuit-page buffer 13 reads and writes data, transmits read data to an external device, and fetches write data.

Here, the writing of data will be described in detail.

The nonvolatile semiconductor memory device 1 receives not only a command and an address for loading write data transmitted from a memory controller 2 but write data.

The data circuit-page buffer 13 receives this write data through the input-output circuit 16 and fetches the write data in the data cache DC.

Next, the sense amplifier SA writes the write data on a selected memory cell MC and the select transistors ST1 and ST2 through the data cache DC at a time corresponding to an instruction from the control circuit 15.

### Column Decoder 14

The column decoder 14 decodes a column address signal input from the address-command register 17 and selects a column direction of the memory cell array 11.

### Control Circuit 15

The control circuit 15 controls the overall operation of the nonvolatile semiconductor memory device 1. That is, the control circuit 15 performs an operation sequence of a write operation of data based on a control signal, a command, and an address supplied from the address-command register 17.

In order to perform this sequence, the control circuit 15 controls an operation of each circuit block included in the nonvolatile semiconductor memory device 1.

For example, the control circuit 15 controls the internal voltage generating circuit 18 to generate predetermined voltages and controls predetermined times at which the predetermined voltages are output to the word lines WL and the bit lines BL through the row decoder 12 and the data circuit-page buffer 13.

Further, the control circuit 15 also participates in the control of input and output states of the input-output circuit 16.

### Input-Output Circuit 16

The input-output circuit 16 receives a command, an address, and write data from an external host device (not illustrated), supplies the command and the address to the address-command register 17, and supplies the write data to the data circuit-page buffer 13.

Further, the read data supplied from the data circuit-page buffer 13 is output to the host device under the control of the control circuit 15.

### Address-Command Register 17

The address-command register 17 temporarily stores the command and the address supplied from the input-output circuit 16, supplies the command to the control circuit 15, and supplies the address to the row decoder 12 and the column decoder 14.

### Internal Voltage Generating Circuit 18

The internal voltage generating circuit 18 generates predetermined voltages under the control of the control circuit 15 during a write operation, a read operation, and an erase operation.

During the write operation, the internal voltage generating circuit 18 generates a voltage VPGM, a voltage VPASS, a voltage VCGR, a voltage VREAD, a voltage USEL_D, a voltage USEL_BG, a voltage PROGVSRC, a voltage VDDSA, and a voltage VSS.

In first to third embodiments, the internal voltage generating circuit 18 supplies the voltage VPGM to the select transistors ST1 and/or ST2 and supplies the voltage VSS (0 V or 0 V to about 1 V) to the word lines WL during the write operation.

During the write operation of the user data on the word lines WL, the voltage VPGM and the voltage VPASS are supplied to a selected word line WL and non-selected word lines WL.

The voltage VPGM has a voltage value at which charges are injected into charge storage layers (described below) included in the memory cells MC (including the select transistors ST), and thresholds of the memory cells MC are shifted into another level.

In addition, the voltage VPASS is applied to the non-selected word lines WL in a selected memory string MS and is optimized to be turned on to the extent that data is not written on the memory cells MC.

In addition, the voltage USEL_D and the voltage USEL_BG cause the dummy memory cell MC and the back gate transistor BG to be turned on.

Further, the internal voltage generating circuit 18 supplies a voltage VCG_V to the selected word line WL and supplies the voltage VREAD to the non-selected word lines WL during a write verification operation.

In addition, the internal voltage generating circuit 18 supplies the voltage VCGR to the selected word line WL and supplies the voltage VREAD to the non-selected word lines WL during the read operation.

### 2. Write Operation

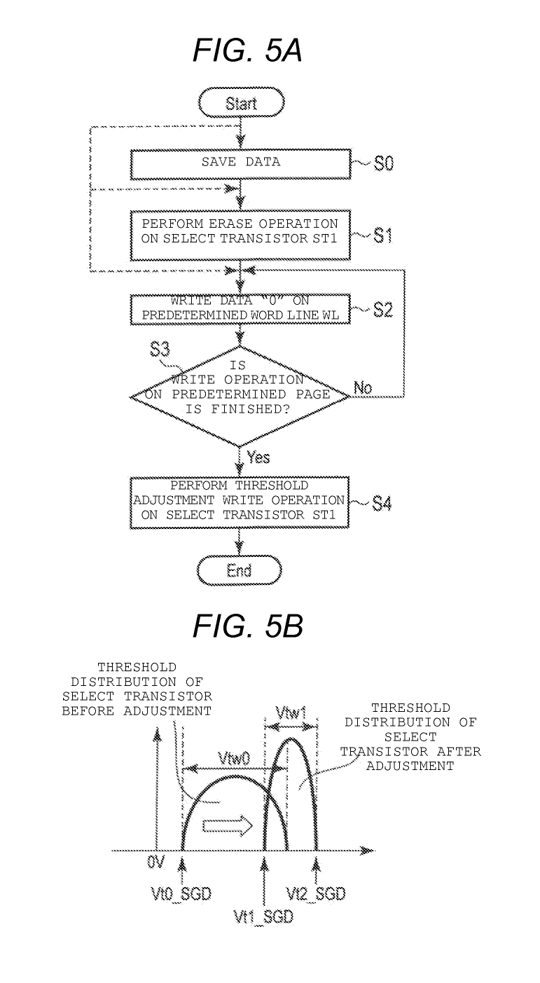

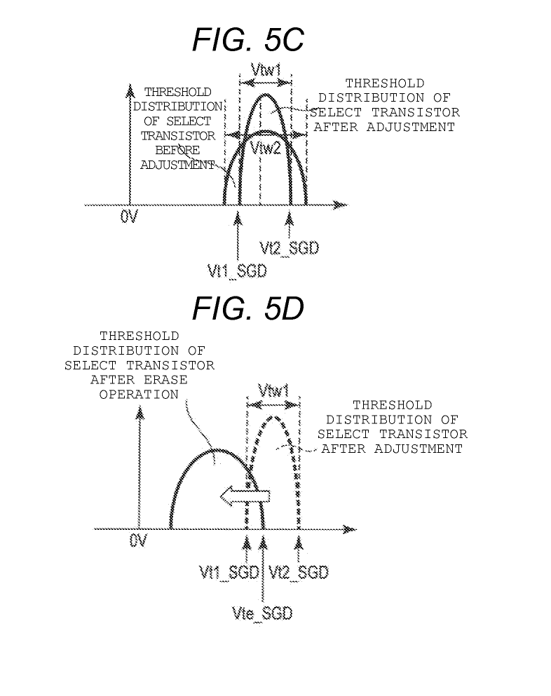

Next, a write operation of the nonvolatile semiconductor memory device according to the first embodiment will be described using FIGS. 5A to 5D. FIG. 5A is a flowchart illustrating a write operation of a select transistor which allows the memory cell array to be controlled in an optimum state. In this case, it is assumed that the memory string MS includes memory cells MC0 to MC7.

In addition, FIG. 5B illustrates a threshold state which is realized by the control of the write operation on the select transistor in FIG. 5A.

In FIG. 5B, first, it is assumed that an initial threshold distribution of the select transistors has a distribution width from level Vt0_SGD to level Vtw0. It is necessary that the distribution width of the threshold of the select transistor satisfy the following conditions such that a normal write operation on the memory cells is appropriately performed.

(1) It is necessary that the Vt distribution width of the select transistors be smaller than a potential difference between a bit line potential (for example, 0 V) during a “0” write operation for increasing the thresholds of the memory cells to a desired level; and a bit line potential (for example, VDDSA=2.5 V) during a “1” write operation for allowing the thresholds of the memory cells not to be shifted.

(2) Further, it is necessary that a voltage margin ΔVgs and the like be considered while anticipating a difference between an on-current and an off-current of the select transistors. In addition, when the distribution width of the thresholds of the select transistors is represented by Vtw_SGD and the potential difference between the “0” write operation and the “1” write operation of the bit lines is represented by ΔVBL, it is necessary that a relationship of Vtw_SGD<ΔVBL−ΔVgs be satisfied.

That is, in FIG. 5B, when the initial distribution width Vtw0 is larger than 2.5 V−ΔVgs, it is necessary that the thresholds of the select transistors be adjusted such that the distribution width is narrower than 2.5 V−ΔVgs.

In addition, when a minimum voltage which may be applied to gates of the select transistors is 0 V, it is necessary that absolute values of the thresholds of the select transistors be threshold voltages such that an off-current having a predetermined value or less flows in a state where a voltage of 0 V is applied to the gates. That is, when the off-current of the lower limit Vt0_SGD of the thresholds of the select transistors is larger than a desired off-current in FIG. 5B, the threshold voltages are increased and adjusted to decrease the off-current.

It is necessary that a drain side select transistor satisfy the above-described two conditions and that a source side select transistor satisfy the latter condition (2). When the select transistors are programmable devices as in the memory cells and do not satisfy the two conditions in the initial state, it is necessary that the threshold distribution be adjusted as illustrated in FIG. 5B to satisfy the desired conditions by performing a write operation on the select transistors. On the other hand, when the select transistors are not programmable, that is, when a layer configuration including a charge storage layer similar to that of the memory cells is not provided between the gates and the semiconductor layer where a channel is formed, it is necessary that the threshold voltages of the select transistors during a process step be optimized to satisfy the above-described conditions. Here, the description is continued under the assumption that the select transistors are programmable.

Unlike a normal write operation on the memory cells, this write operation is not an operation of storing rewritable data but an operation of adjusting the thresholds such that the select transistors are desirably operated as described above. When a threshold of a target select transistor is lower than a verification level Vt1_SGD of the target after the threshold adjustment, it is necessary that the write operation be continued until the threshold exceeds the level.

An example of a desirable control method during the adjustment of the thresholds of the select transistors will be described below.

As illustrated in FIG. 5A, first, the control circuit 15 saves user data (Step S0).

Specifically, the internal voltage generating circuit 18 applies the voltage VCGR to the select word line WL and applies the voltage VREAD to the non-selected word line WL, and the data circuit-page buffer circuit 13 senses a voltage (or current) flowing through the bit lines BL.

As a result, the data circuit-page buffer circuit 13 reads data from a user data region in units of page and stores the read data in another user data region.

Here, when it is not necessary that data be saved in a block which is a target of adjusting the thresholds of the select transistors, this Step S0 is not necessarily performed.

Next, the control circuit 15 shifts the thresholds of the select transistors ST1 to a predetermined erase level (S1).

FIG. 5D illustrates a threshold distribution of the select transistors after the erase operation.

This erase operation is necessary because a threshold distribution after the write operation described below is not narrowed when the thresholds of the select transistors before performing the above-described series of operations are distributed to exceed a target range of the write operation described below, that is, to exceed the upper limit Vt2_SGD of the threshold voltages after the adjustment. That is, in a memory cell in which a threshold level after a write operation exceeds a predetermined threshold level (Vt2_SGD), a threshold distribution after a write operation which is subsequently performed cannot be narrowed. Therefore, the erase operation illustrated in FIG. 5D is necessary.

When the threshold distribution before the adjustment is positioned to be lower than the threshold distribution after the adjustment as illustrated in FIG. 5B, this Step S1 may also be skipped. As illustrated in FIG. 5C, Step S1 is necessary when an upper end of the threshold distribution before the adjustment exceeds Vt2_SGD. Accordingly, a predetermined erase level of the erase operation only has to satisfy a condition that an upper end (Vte_SGD in FIG. 5D) of a threshold distribution after the erase operation is sufficiently lower than Vt2_SGD. Although the detailed description will be omitted, an erase verification operation is performed at level Vte_SGD after applying an erase pulse to the select transistors. This erase operation step is finished when the threshold voltages of substantially all the select transistors are lower than Vte_SGD.

Specifically, it is assumed that the erase operation of the select transistors is performed on the drain side select transistors.

During an erase pulse applying operation, an erase voltage (for example, 20 V) is applied to cell source lines and the bit lines, a voltage of 0.5 V is applied to gates of the drain side select transistors, an intermediate voltage of, for example, about 10 V is applied to the dummy word lines and normal word lines, and a voltage close to the intermediate voltage or the erase voltage is applied to a gate of the source side select transistor to erase the drain side select transistor.

In addition, during an erase verification operation for checking a state after the erase operation, the voltage Vte_SGD is applied to the gate of the selected drain side select transistor, a read pass voltage is applied to the dummy word lines and the normal word lines to allow the memory cells thereof to be in an on-state, and a predetermined voltage is applied to the gate of the source side select transistor to allow a cell current to flow therethrough. The current flowing through the bit lines in this state is sensed by the sense amplifier included in the data circuit.

Next, the control circuit 15 writes data “0” (in the case of one bit) on a predetermined page (for example, the word lines WL0 to WL7) (S2). That is, thresholds of the memory cells MC0 to MC7 connected to the word lines WL0 to WL7 are increased to another level.

This write operation is performed to write not any data but a high threshold on memory cells of a predetermined word line region. During a select transistor write operation described below, a voltage around 0 V is applied to target word lines of the write operation. Therefore, in a state where this gate voltage is applied, the write operation is performed such that the memory cells are in an off-state.

In this way, when data “0” is written on the predetermined page (S3, YES), the control circuit 15 performs a write operation of the select transistor ST1 (S4).

On the other hand, when data writing on the desired page is not finished in Step S3 (S3, No), the process returns to Step S2, and data is written on a write target page.

When two bits of data may be stored in the memory cells MC, it is preferable that the thresholds of the memory cells MC be written from the erase level to level “B” or level “C” by the above-described write operation.

Specifically, the internal voltage generating circuit 18 applies the voltage VPGM to the signal lines SGD, applies the voltage VPASS to the signal lines SGS, and applies the voltage VSS (0 V or about 1 V) to the word lines WL0 to WL47. The internal voltage generating circuit 18 applies a voltage to the back gate transistor BG such that the back gate transistor BG is turned off.

At this time, the threshold distribution width after the write operation of the select transistors may be controlled to be in a desired range by applying a write allowing voltage (for example, 0 V) or a write preventing voltage (for example, a voltage VDDSA=2.5 V) to the bit lines BL. During this write operation, actually, a write cycle including a write pulse application operation and a write verification operation following the write pulse application operation is repeated, and the write cycle is repeated until the thresholds of all the select transistors which perform the write operation are in a desired threshold state. During the write verification operation, it is determined whether or not the thresholds of the select transistors are a desired threshold or more.

When the thresholds of the select transistors exceed the desired threshold, during the write pulse application operation of the next write cycle, a non-write potential (for example, 2.5 V) is applied to the bit lines by a sense amplifier-data circuit which is connected to the select transistors through the bit lines. In addition, during the write verification operation following the write pulse application operation, a state of a write pulse is stored irrespective of the sensing result of the bit lines.

Conversely, when the thresholds of the select transistors do not exceed the desired threshold, during the write pulse application operation of the next write cycle, a potential (for example, 0 V) for allowing a write operation to be continuously performed on the bit lines is applied to the bit lines by the sense amplifier-data circuit which is connected to the select transistors through the bit lines. In addition, during the write verification operation, the current flowing through the bit lines is sensed as usual.

### 3. Timing Diagram (Part 1)

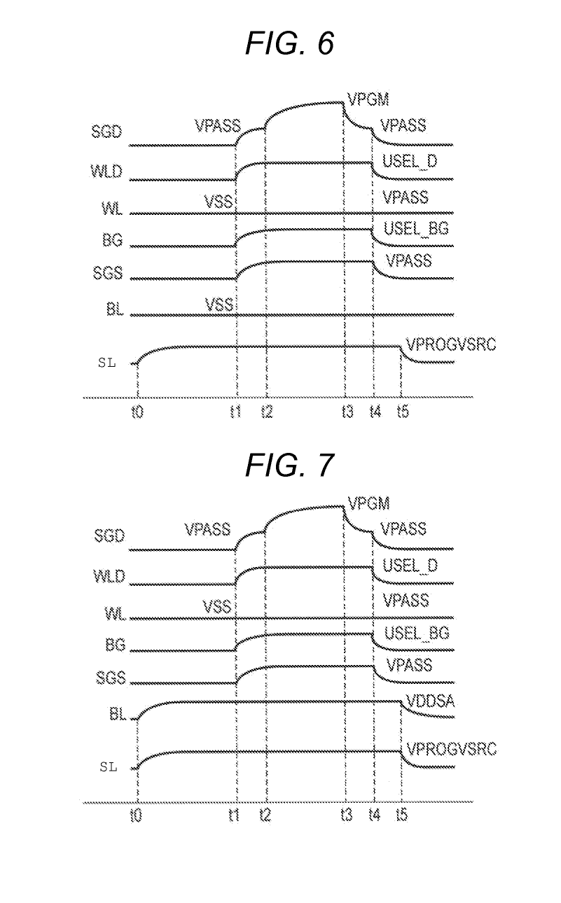

Next, a voltage level of each signal line which is changed over time during a non-write operation on the select transistor ST1 will be described using FIG. 6. The signal line SGD, the dummy word lines WLD, the word lines WL, the gate signal line BG of the back gate transistor, the signal line SGS, the bit lines BL, and the source line SL are illustrated in the vertical axis, and the time t is illustrated in the horizontal axis. The description of the same operation as that of FIG. 6 will not be repeated.

As illustrated in FIG. 6, after time t0, the internal voltage generating circuit 18 applies a voltage of, for example 3 V (for example, 2.5 V) to the bit lines BL as the write preventing voltage.

The bit line potential is increased by 3 V compared to the case of the above-described write operation. Therefore, a potential difference between the gate of the select transistor and a Si channel is decreased by 3 V. When it is assumed that a difference between write characteristics of the select transistors, that is, a voltage difference between an easy-to-write select transistor and a hard-to-write select transistor is 2.5 V, the decrease of 3 V of the write voltage applied to the select transistors implies a non-writable state. Accordingly, when 0 V is applied to the bit lines to perform a write operation on the select transistor ST1, and when it is determined by the write verification operation that the desired threshold Vt1_SGD is reached, an additional write operation is prevented by applying a non-write voltage to the bit lines.

In this case, the voltage VPASS is applied to the signal line SGS. For example, even when the select transistor ST2 is turned on, the voltage VSS is applied to the word lines WL, and thus a current does not flow from the source lines SL to the bit lines BL.

When it is determined by the verification operation on the select transistors that the desired threshold level is not reached, it is necessary that the write pulse application operation be continuously performed on the select transistors connected to the bit lines. Therefore, 0 V is applied to the bit lines during the next write cycle to perform a write operation again. The control circuit 15 simultaneously performs a write operation on a plurality of select transistors (for example, the number corresponding to 8 KB) connected to the gate signal lines SGD. Therefore, ideally, the write cycle is repeated until the thresholds of all the select gates reach the desired threshold.

### 4. Timing Diagram (Part 2)

Next, a voltage level of each signal line which is changed over time during a write operation on the select transistor ST1 will be described using FIG. 7. The signal line SGD, the dummy word lines WLD, the word lines WL, the gate signal line BG of the back gate transistor, the signal line SGS, the bit lines BL, and the source line SL are illustrated in the vertical axis, and the time t is illustrated in the horizontal axis.

The voltage level of the signal line SGD illustrated in FIG. 7 is a value of, for example, the memory string MS0 included in a sub-block SB0.

In addition, the voltage level of the signal line SGS is a value of all the memory strings MS included in the sub-block SB0, that is, the memory strings MS0 to MS11.

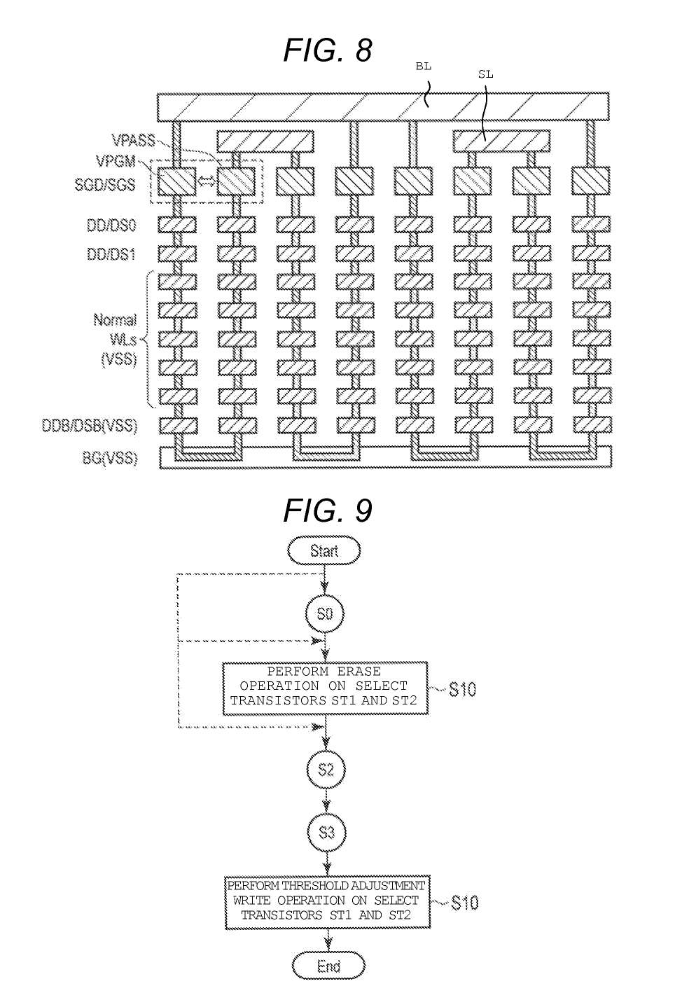

In addition, a state of a write operation at time t2 to t3 described below will be described using FIG. 8. FIG. 8 is a cross-sectional view illustrating the memory strings MS and a conceptual diagram when the write voltage and the like are applied.

As illustrated in FIG. 7, at time t0, the internal voltage generating circuit 18 applies 0 V to the signal lines SGS and SGD, applies the voltage VPROGVSRC (for example, 2.5 V) to the source lines SL, and applies the write voltage (0 V) to the bit lines BL.

Next, at time t1, the control circuit 15 controls the internal voltage generating circuit 18 to apply the voltage VSS to the word lines WL, to apply the USEL_D to the dummy word lines WLD, to apply the voltage USEL_BG to the signal lines BG, to increase the voltage applied to the signal line SGS from 0 V to the voltage VPASS, and to increase the voltage supplied to the signal line SGD from 0 V to the voltage VPASS.

Next, at time t2, the internal voltage generating circuit 18 increases the voltage applied to the signal line SGD to the voltage VPGM. At this time, 0 V is applied to the bit lines, and the write voltage VPGM is applied to the gate of the select transistor ST1. Therefore, charges are injected to the charge storage layer of the select transistor ST1, and the threshold increases.

As clearly seen from the timing diagram of FIG. 7, although the dummy memory cells MC are turned on, the voltage VSS is applied to the word lines WL. Therefore, a channel is not formed on the memory string MS of FIG. 7.

Therefore, as illustrated in FIG. 8, the voltage VPASS is applied to the signal line SGS. Therefore, for example, even when the select transistor ST2 is turned on, the current does not flow from the source lines SL to the bit lines BL.

### Effects According to First Embodiment

With the nonvolatile semiconductor memory device according to the first embodiment, the following effect (1) may be obtained.

(1) A write operation may be performed on the select transistors while alleviating a potential difference between the gate signal line SGD of the select transistor ST1 and the gate signal line SGS of the select transistor ST2.

First, a comparative example is assumed in which, when the write voltage is applied to adjacent signal lines SGD in the memory cell array, 0 V is applied to the signal lines SGS adjacent to the signal lines SGD. In this case, a large potential difference may be generated between the adjacent signal lines SGD and SGS.

However, in the first embodiment, a potential difference between the signal lines SGD and SGS may be reduced by the application of the intermediate voltage VPASS.

In order to achieve this configuration, in the nonvolatile semiconductor memory device according to the first embodiment, the threshold distribution of the memory cells MC is increased (for example, to level “C”) by writing, for example data “0” to the several pages of memory cells MC before writing data on the select transistor ST1 as described above.

Therefore, since the thresholds of the memory cells MC are distributed above 0 V, the memory cells are in the cut-off state by applying the voltage VSS to the word lines WL. As a result, it is possible to prevent a through-current from flowing between the source lines SL to which the voltage VDDSA is applied and the bit lines BL to which a voltage of 0 V or about 3 V is applied. That is, a predetermined number of memory cells which perform a write operation perform the same function as that of the select gates.

With the above-described configuration, a predetermined write operation may be performed on the select transistors while alleviating a potential difference between the select transistors ST1 and ST2. That is, the size of a slit between the select transistors ST1 and ST2 is not limited to a write operation of the threshold adjustment of the select gates.

### Second Embodiment

Next, a nonvolatile semiconductor memory device according to a second embodiment will be described using FIGS. 9 to 11. The second embodiment is different from the first embodiment, in that data is simultaneously written on the select transistors ST1 and ST2.

Since the configurations of the second embodiment are the same as those of the first embodiment, the description thereof will not be repeated. In addition, regarding the operations, only different points will be described.

### 1. Write Operation

Next, a write operation of the nonvolatile semiconductor memory device according to the second embodiment will be described using FIG. 9. FIG. 9 is a flowchart when a write operation is performed on the select transistors ST1 and ST2. The description of the same operations as those of the above-described embodiment will not be repeated.

As illustrated in FIG. 9, first, the control circuit 15 saves data (Step S0) as in the first embodiment when it is necessary that data stored in a block which is a write target of the threshold adjustment of the select transistors be saved in another block. Next, in this embodiment, an erase operation is performed on both the select transistors ST1 and ST2. As described above, this operation is performed to shift the thresholds to be lower than a desired threshold range before increasing the thresholds of the select gates.

However, as in the first embodiment, when the select gates are excessively erased, there may be a case where the memory string cannot be controlled by the select gates. Therefore, when the threshold range before a write operation is lower than a final target threshold range, the erase operation of Step S1 may be skipped.

Next, as in the first embodiment, in Steps S2 and S3, a through-current is prevented from flowing between the bit lines and the cell source lines by performing a write operation on a predetermined word line.

Next, the control circuit 15 performs a write operation on the select transistors ST1 and ST2 (S10).

Specifically, the control circuit 15 controls the internal voltage generating circuit 18 to apply the voltage VPGM to the signal lines SGD and SGS and to apply the voltage VSS to the word lines WL such that the memory cells MC are turned off. In addition, during this write operation, as described above, a voltage of 0 V is applied to the bit lines BL when the write operation is necessary, and a voltage of, for example about 3 V is applied to the bit lines BL when the write operation is unnecessary.

### 2. Time Chart

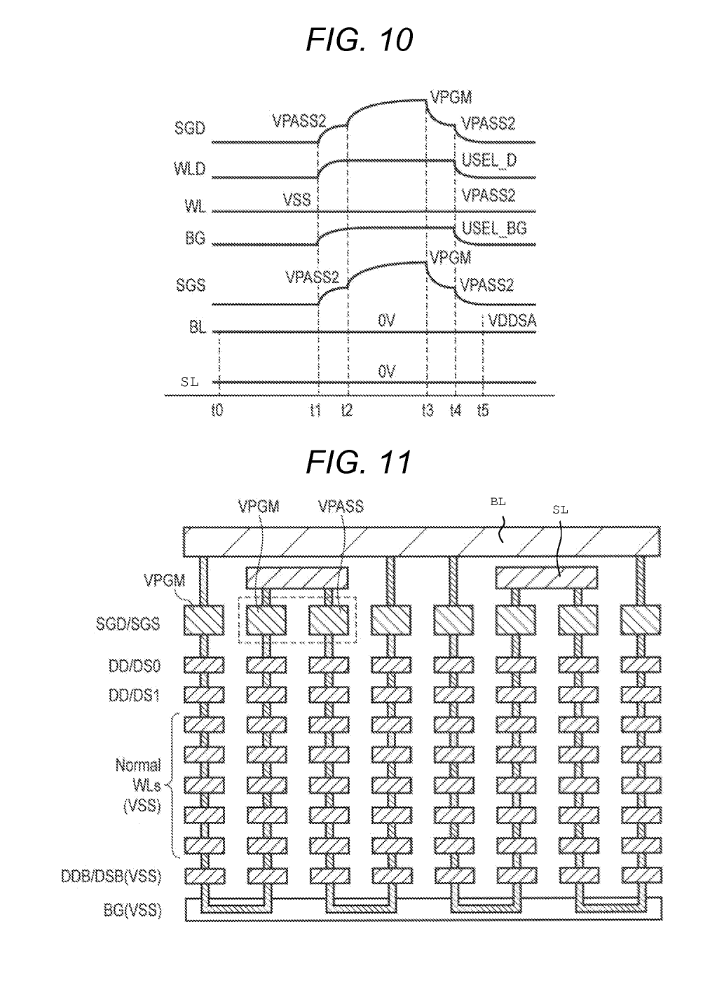

Next, a voltage level of each signal line which is changed over time during write and non-write operations on the select transistor will be described using FIG. 10. The signal line SGD, the dummy word lines WLD, the word lines WL, the gate signal line BG of the back gate transistor, the signal line SGS, the bit lines BL, and the source line SL are illustrated in the vertical axis, and the time t is illustrated in the horizontal axis.

The voltage levels of the signal lines SGD and SGS illustrated in FIG. 10 are values of, for example, the memory string MS0 included in the sub-block SB0.

In addition, a state of voltage application at time t2 to t3 described below will be described using FIG. 11. FIG. 11 is a cross-sectional view illustrating the memory strings MS and a conceptual diagram when the write voltage and the like are applied.

The description of the same operations as those of FIGS. 6 and 7 will not repeated.

At time t1, the control circuit 15 controls the internal voltage generating circuit 18 to increase the voltage applied to the signal line SGS of the memory string MS0 to the voltage VPASS.

Next, at time t2, the control circuit 15 controls the internal voltage generating circuit 18 to apply the voltage VPGM to the signal line SGS of the memory string MS0. In this way, data is simultaneously written on the select transistors ST1 and ST2.

The internal voltage generating circuit 18 applies the voltage VPASS to the signal lines SGD and SGS of the other memory strings MS1 to MS11.

FIG. 11 illustrates a state of the above-described voltage application.

As illustrated in FIG. 11, the write operation is performed on the select transistors ST1 and ST2 by applying the voltage VSS to the word lines WL and applying the voltage VPGM to the select transistors ST1 and ST2 of the memory string MS0.

The verification operation after the write operation is performed on the select transistor ST1 as described above. As described above, the write operation is performed by repeating the write cycle including the write pulse application operation and the verification operation. Based on the result of the write verification operation, when the threshold of the select transistor ST1 does not reach the desired threshold, a bit line potential of 0 V is applied to the bit lines during the next write pulse application operation, and when the threshold of the select transistor ST1 is increased to be the desired threshold or more, a bit line potential of about 3 V is applied to the bit lines during the next write pulse application operation. On the other hand, in the select transistor ST2, 0 V is applied to a cell source line SL. Since the write voltage VPGM is applied to the signal line SGS, when 0 V is applied to the cell source line SL, the same write operation as that of a state where 0 V is applied to the bit lines is performed on the select transistor ST1.

That is, the write operation is continuously performed on the select transistor ST2 until the select transistor ST1 is in a predetermined state where the write operation is finished as a result of the verification operation on the select transistor ST1.

The reason is as follows. It is necessary that the threshold distribution of the select transistor ST1 be narrowed due the overlapping with the voltage applied to the bit lines BL. The threshold distribution of the select transistor ST2 may be wide as long as the lower limit thereof is the predetermined threshold or more.

### Effects According to Second Embodiment

With the nonvolatile semiconductor memory device according to the second embodiment, the above-described effect (1) may be obtained.

That is, in the second embodiment, as illustrated in FIG. 11, the write voltage VPGM may be applied to the select transistor ST2 adjacent to the select transistor ST1.

Accordingly, a potential difference between the select transistors ST1 and ST2 may be alleviated, and the size of a slit between the select transistors ST1 and ST2 is not limited by a write operation on the select gates.

### Third Embodiment

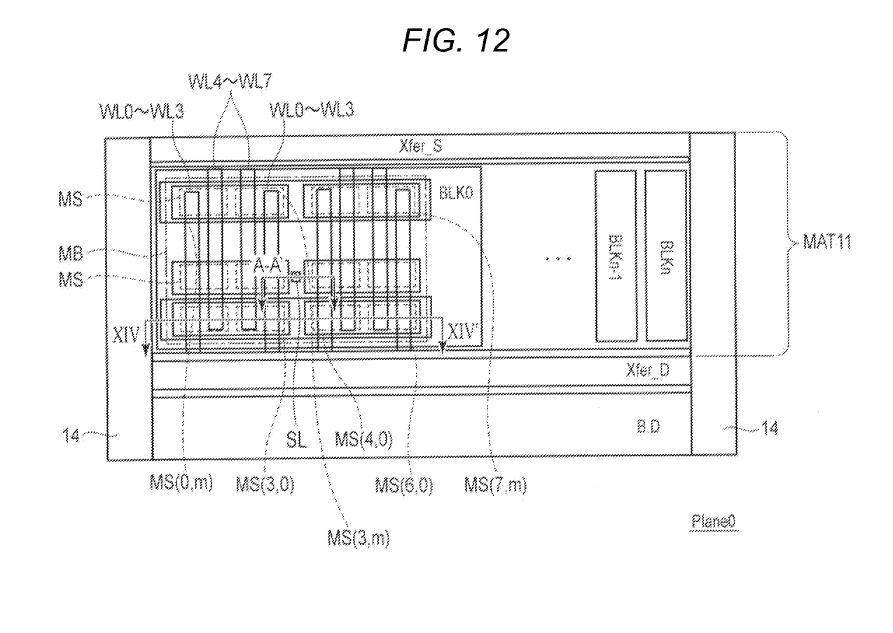

Next, a nonvolatile semiconductor memory device according to a third embodiment will be described using FIGS. 12 to 19.

In the memory string MS according to the third embodiment, unlike the above-described configuration, the select transistor ST2, the dummy word lines WL, the word lines WL, and the select transistor ST1 are formed on the semiconductor layer in order from below.

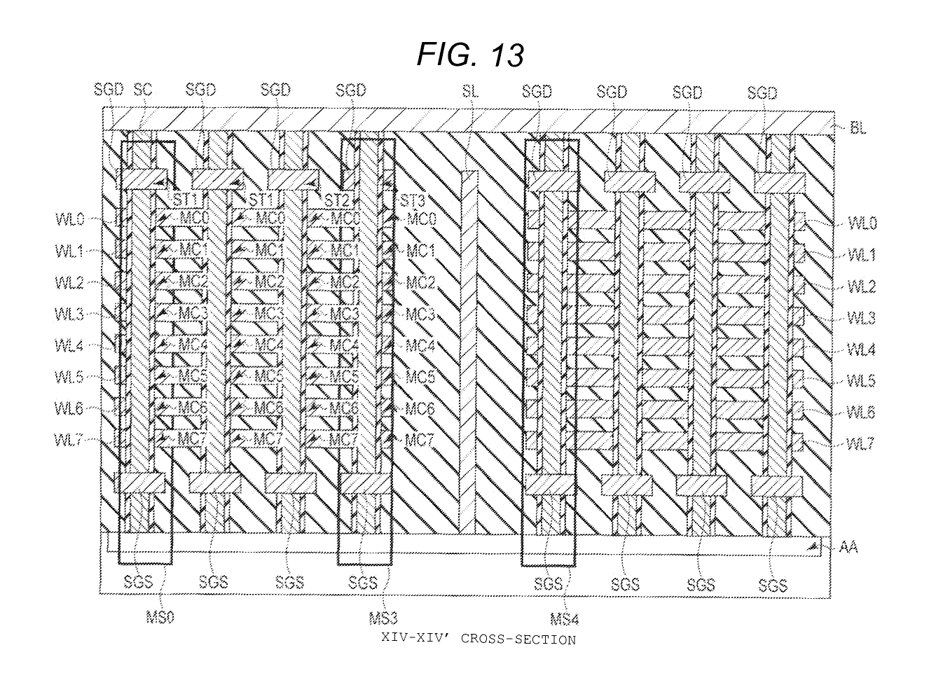

That is, in a memory cell array according to the third embodiment, the select transistors ST1 are adjacent to each other, and the select transistors ST2 are adjacent to each other between adjacent memory strings MS. This state is illustrated in FIGS. 12 and 13.

### 1. Configuration of Memory Cell Array

A configuration of the memory cell array will be described using FIGS. 12 and 13. The description of the same configurations as those of the above-described embodiments will not be repeated.

FIG. 12 is a plan view illustrating the memory cell array 11 according to the third embodiment. Although described below, as illustrated in FIG. 12, for example, a columnar source line SL is disposed between the memory strings MS.

FIG. 13 is a cross-sectional view taken along line XIV-XIV′ of FIG. 12.

Actually, although the sub-block SB0 includes the memory strings MS0 to MS11, the memory strings MS0 to MS7 are illustrated for convenience of description. Since the configurations of the memory strings MS0 to MS7 are the same, the memory string MS0 will be described as an example in this embodiment.

As illustrated in FIG. 13, the memory string MS0 includes the select transistors ST2, dummy memory cells MCDS0 and MCDS1 (not illustrated), the memory cells MC0 to MC23, the dummy memory cells MCDD0 and MCDD1 (not illustrated), the select transistors ST1, and a semiconductor layer SC0 that is formed to penetrate the above-described components in a normal line direction of CPWELL, all of which are formed on CPWELL in order from below.

With such a configuration, the signal lines SGD are adjacent to each other, and the signal lines SGS are adjacent to each other between the adjacent memory strings MS.

Further, the source line SL is formed to be parallel to the semiconductor layer SC between the memory strings MS3 and MS4 and is formed in the normal line direction of CPWELL.

This source line SL may be formed in a depth direction of the drawing in, for example, a wall shape or a strut shape which is the same as that of the semiconductor layer SC. Here, a case where the source line SL has a strut shape as described in FIG. 12 will be described.

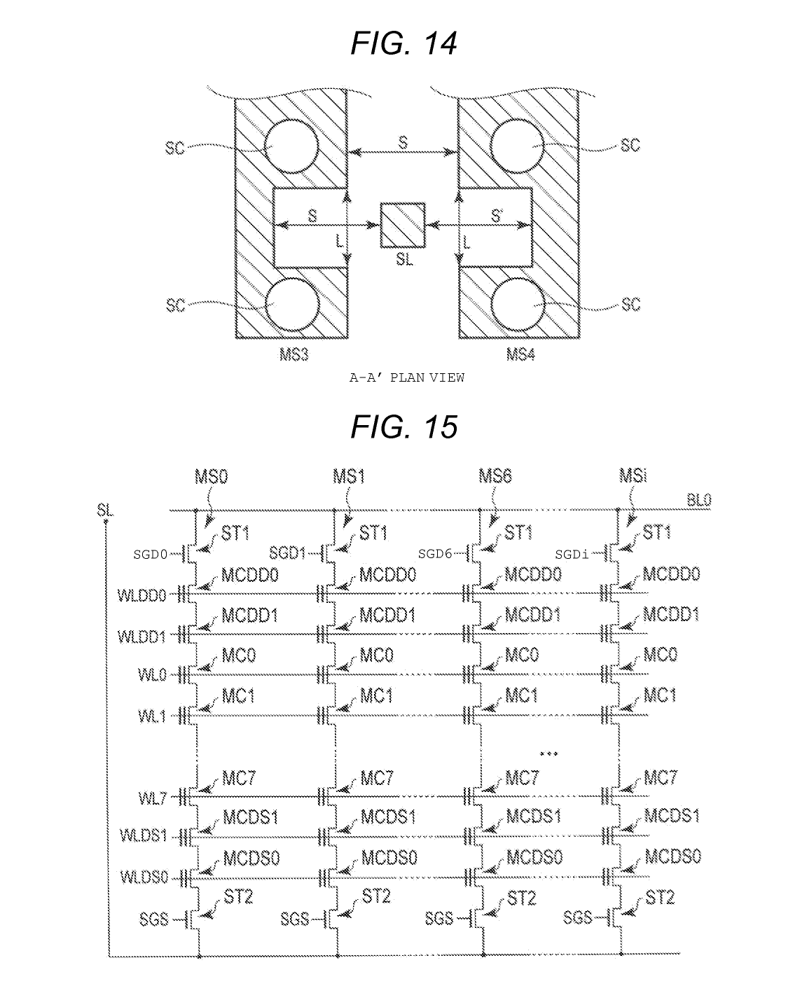

FIG. 14 illustrates the memory cell array in which the source line SL has a strut shape. FIG. 14 is a plan view illustrating the memory cell array when seen from above along line A-A′.

As illustrated in FIG. 14, when the source line SL is disposed between the memory string MS4 and the memory string MS5 adjacent thereto, there is a problem of a potential difference between the signal lines SGD and the source line SL.

For example, the distance between adjacent word lines which penetrate the adjacent memory strings MS3 and MS4 will be referred to as “S”. The “S” is a value determined in consideration of a potential difference between adjacent word lines WL. That is, the distance is determined such that, even when a given constant potential difference is generated between the word lines WL, a leakage current having a predetermined value or more is not generated and short-circuiting does not occur between the word lines WL.

In addition, the distance between the word lines and the source line SL will be referred to as “S′”. During an erase operation or a write operation, a maximum potential difference applied between the source line SL and the word lines or the gates of the select transistors is substantially the same as a potential difference between the word lines of a block boundary. Therefore, S and S′ are set to be the same. However, since this configuration varies in accordance with the operation control which is assumed, S and S′ may be different from each other in the design stage.

### 2. Equivalent Circuit of Memory Cell Array 11

Next, an equivalent circuit of the sub-block SB0 will be described using FIG. 15. That is, FIG. 15 is an equivalent circuit diagram illustrating the memory strings MS0 to MS7 connected to the bit line BL0.

As illustrated in FIG. 15, the memory strings MS0 to MS7 are connected to the bit line BL0.

Each memory string MS includes a plurality of memory cells MC which are interposed between the select transistors ST1 and ST2.

Since configurations other than the above-described configurations are the same as those of the circuits according to the first and second embodiments, the description thereof will not be repeated.

### 3. Timing Diagram (Write Operation on Select Transistor ST1)

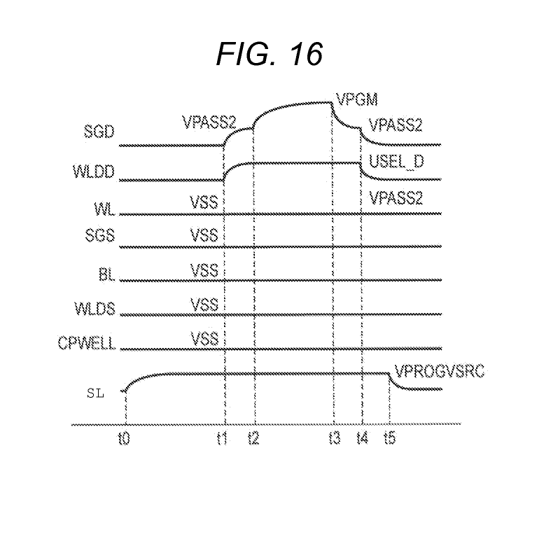

Next, a write operation (part 1) of the nonvolatile semiconductor memory device according to the third embodiment will be described using FIG. 16. FIG. 16 is a timing diagram illustrating the voltage level of each signal line during a write operation on the select transistor ST1 of the memory string MS0. Different operations from those of the above-described time charts will be described.

As illustrated in FIG. 16, after time t0, the control circuit 15 controls the internal voltage generating circuit 18 to apply the voltage VSS to not only the word lines WL and the dummy word lines WLDS but the signal line SGS and to apply the voltage VPGM to the signal line SGD.

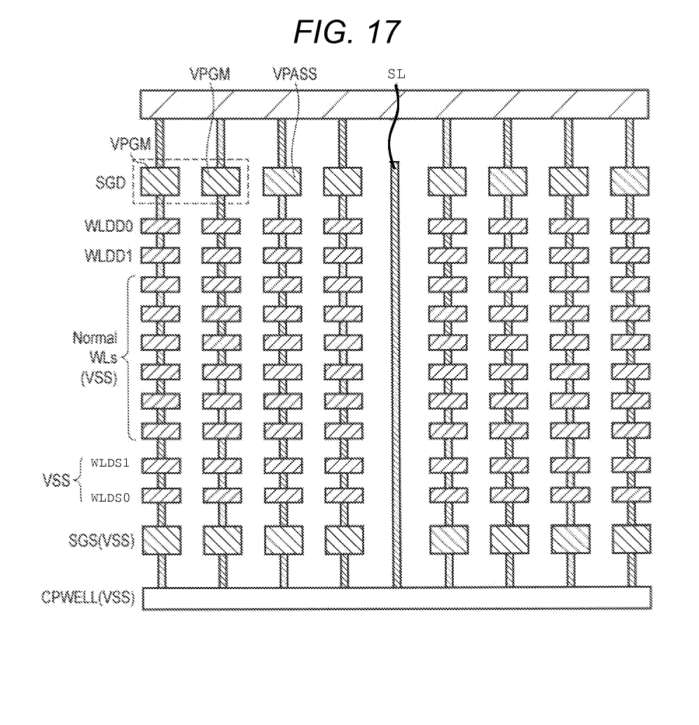

This state is illustrated in FIG. 17. FIG. 17 is a cross-sectional view illustrating the sub-block SB0 and is a conceptual diagram during a write operation on the select transistor ST1 of the memory string MS0.

As illustrated in FIG. 17, under the control of the control circuit 15, the internal voltage generating circuit 18 applies the voltage VPGM to the signal line SGD of the memory string MS0, applies the voltage USEL_D to the dummy word lines WLDD0 and WLDD1, applies the voltage VSS to the word lines WL and the dummy word lines WLDS0, and WLDS1, and CPWELL, applies the voltage of, for example, VDDSA to the source line SL as the voltage VPROGVSRC.

In addition, the control circuit 15 controls the internal voltage generating circuit 18 to apply the voltage VPASS to the signal lines SGD of the memory strings MS1 to MS11.

In this way, in the configuration according to the third embodiment, the write operation is performed by applying the voltage VSS to the signal line SGS and applying the voltage VPGM to the signal line SGD.

Although not illustrated in FIG. 16, the voltage VPASS is applied to the signal lines SGD of the non-selected memory strings MS1 to MS11.

### 4. Timing Diagram (Write Operation on Select Transistor ST2)

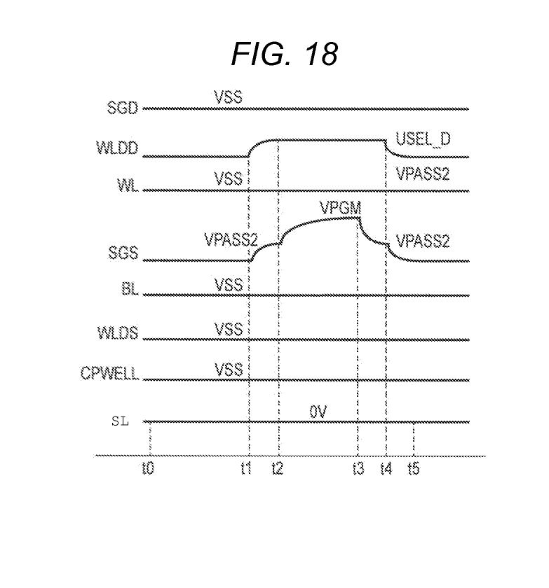

Next, a write operation (part 2) of the nonvolatile semiconductor memory device according to the third embodiment will be described using FIG. 18. FIG. 18 is a timing diagram illustrating the voltage level of each signal line during a write operation on the select transistor ST2 of the memory string MS0. Different operations from those of the above-described time charts will be described.

In this case, as illustrated in FIG. 18, after time t0, the control circuit 15 controls the internal voltage generating circuit 18 to apply the voltage VSS to the signal line SGD, to apply the voltage VPASS to the signal line SGS at time t1, and to apply the voltage VPGM to the signal line SGS at time t2.

In this way, in the configuration according to the third embodiment, when a write operation is performed on the select transistor ST2, the write operation is performed by applying the voltage VSS to the signal line SGD and CPWELL and applying the voltage VPGM to the signal line SGS.

Even in this case, the voltage VPASS is applied to the gates (signal lines SGS) of the select transistors ST2 of the non-selected memory strings MS1 to MS11 each of which is adjacent to the select transistor ST2.

In this case, there is a problem of a potential difference between the voltage VPGM applied to the signal line SGS and the voltage VSS applied to CPWELL.

A breakdown voltage countermeasure is taken by interposing an insulating film between the select transistor ST2 and CPWELL.

Specifically, an insulating film having a thickness (for example, 400 Å (angstroms) larger than that of an insulating film used in a high breakdown voltage transistor is interposed between the select transistor ST2 and CPWELL.

In the third embodiment, for example, Step S2 and S3 of FIGS. 5A and 9 are not necessarily performed.

The reason is as follows. When data is written on the select transistor ST1, the voltage VSS may be applied to the signal line SGS. When data is written on the select transistor ST2, the voltage VSS may be applied to the signal lines SGD. Therefore, a through-current may be prevented.

### Effects According to Third Embodiment

With the nonvolatile semiconductor memory device according to the third embodiment, the above-described effect (1) may be obtained.

That is, the internal voltage generating circuit 18 applies the voltage VPASS to the gates of the select transistors ST1 of the non-selected memory strings MS1 to MS11 which are adjacent to the select transistors ST1 which are write targets.

Accordingly, during the write operation, a potential difference between the adjacent select transistors ST1 may be reduced, and the size of a slit between the adjacent select transistors ST1 is not limited by a write operation on the select gate. Even when data is written on the select transistor ST2, the same effects may be obtained.

In the respective embodiments, the following configurations may be adopted.

### (1) Read Operation

A voltage which is applied to the selected word line during a read operation at level A is, for example, in a range of 0 V to 0.55 V. However, the voltage is not limited to this range and may be in any range of 0.1 V to 0.24 V, 0.21 V to 0.31 V, 0.31 V to 0.4 V, 0.4 V to 0.5 V, and 0.5 V to 0.55 V.

A voltage which is applied to the selected word line during a read operation at level B is, for example, in a range of 1.5 V to 2.3 V. However, the voltage is not limited to this range and may be in any range of 1.65 V to 1.8 V, 1.8 V to 1.95 V, 1.95 V to 2.1 V, and 2.1 V to 2.3 V.

A voltage which is applied to the selected word line during a read operation at level C is, for example, in a range of 3.0 V to 4.0 V. However, the voltage is not limited to this range and may be in any range of 3.0 V to 3.2 V, 3.2 V to 3.4 V, 3.4 V to 3.5 V, 3.5 V to 3.6 V, and 3.6 V to 4.0 V.

The time (tR) of the read operation may be in any range of, for example, 25 μs to 38 μs, 38 μs to 70 μs, and 70 μs to 80 μs.

### (2) Write Operation

The write operation includes a programming operation and a verification operation as described above. A voltage which is initially applied to the selected word line during the programming operation is in a range of, for example, 13.7 V to 14.3 V. However, the voltage is not limited to this range and may be in any range of 13.7 V to 14.0 V and 14.0 V to 14.6 V.

A voltage which is initially applied to the selected word line during a write operation of an odd-numbered word line and a voltage which is initially applied to the selected word line during a write operation of an even-numbered word line may be changed.

When the programming operation is performed based on an incremental step pulse program (ISPP), a step-up voltage may be, for example, about 0.5 V.

In addition, the voltage which is applied to the non-selected word lines may be in a range of, for example, 6.0 V to 7.3 V. The voltage is not limited to this range and may be in a range of 7.3 V to 8.4 V or may be 6.0 V or lower.

The applied pass voltage may vary in accordance with whether the non-selected word line is an odd-numbered word line or an even-numbered word line.

The time (tProg) of the write operation may be in any range of, for example, 1,700 μs to 1,800 μs, 1,800 μs to 1,900 μs, and 1,900 μs to 2,000 μs.

### (3) Erase Operation

A voltage that is initially applied to a well, which is formed on an upper portion of a semiconductor substrate and above which the above-described memory cells are formed, is in a range of, for example, 12 V to 13.6 V. The voltage is not limited to this range and may be in any range of 13.6 V to 14.8 V, 14.8 V to 19.0 V, 19.0 V to 19.8 v, and 19.8 V to 21 V.

The time (tErase) of the erase operation may be in any range of, for example, 3,000 μs to 4,000 μs, 4,000 μs to 5,000 μs, and 4,000 μs to 9,000 μs.

### (4) Structure of Memory Cell

A charge storage layer is provided on a semiconductor substrate (silicon substrate) with a tunnel insulating film having a thickness of 4 nm to 10 nm interposed therebetween. This charge storage layer may have a stacked structure which includes an insulating film having a thickness of 2 nm to 3 nm and formed of SiN, SiON, or the like and a polysilicon layer having a thickness of 3 nm to 8 nm. In addition, a metal such as Ru may be added to the polysilicon layer. An insulating film is provided on the charge storage layer. This insulating film includes, for example, a lower High-k layer having a thickness of 3 nm to 10 nm, an upper High-k layer having a thickness of 3 nm to 10 nm, and a silicon oxide layer having a thickness of 4 nm to 10 nm that is interposed between the upper and lower High-k layers. The High-k layers are formed of, for example, HfO. In addition, the thickness of the silicon oxide layer may be greater than that of the High-k layers. A control electrode having a thickness of 30 nm to 70 nm is formed on the insulating film with a work function adjusting material layer having a thickness of 3 nm to 10 nm interposed therebetween. The work function adjusting material layer is formed of a metal oxide such as TaO or a metal nitride such as TaN. The control electrode may be formed of W or the like.

In addition, air gaps may be formed between the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a plurality of memory cells electrically connected in series between first and second select transistors and stacked above a semiconductor substrate;
a voltage generation circuit; and
a controller configured to control the voltage generation circuit to apply a write voltage to at least one the memory cells before a write operation is performed on the first select transistor and, during the write operation on the first select transistor, apply a first voltage to gates of the memory cells, a second voltage that is higher than the first voltage to a gate of the second select transistor, and a third voltage that is higher than the second voltage to a gate of the first select transistor.

2. The device according to claim 1, wherein the memory cells include a first group of memory cells that is electrically connected in series between the first select transistor and the semiconductor substrate and a second group of memory cells that is electrically connected in series between the second select transistor and the semiconductor substrate.

3. The device according to claim 2, further comprising:
a back gate transistor electrically connected between the first group of memory cells and the second group of memory cells.

4. The device according to claim 3, further comprising:
a plurality of word lines stacked above the semiconductor substrate;
a first semiconductor column extending through the word lines, the first group of memory cells being located at intersections of the first semiconductor column and the word lines; and
a second semiconductor column extending through the word lines, the second group of memory cells being located at intersections of the second semiconductor column and the word lines.

5. The device according to claim 4, further comprising:
first and second select signal lines stacked above the word lines at a same level above the word lines, wherein
the first semiconductor column extends through the first select signal line and the first select transistor is located at an intersection of the first select signal line and the first semiconductor column, and
the second semiconductor column extends through the second select signal line and the second select transistor is located at an intersection of the second select signal line and the second semiconductor column.

6. The device according to claim 1, further comprising:
a bit line, wherein a first end of the first select transistor is electrically connected to the bit line and a second end of first select transistor is electrically connected to the memory cells; and
a source line, wherein a first end of the second select transistor is electrically connected to the source line and a second end of second select transistor is electrically connected to the memory cells.

7. The device according to claim 6, wherein the first and second select transistors are located substantially the same distance away from the semiconductor substrate and have no other transistors or memory cells therebetween.

8. The device according to claim 1, wherein the first and second select transistors each include a charge storage layer.

9. A nonvolatile semiconductor memory device comprising:
a plurality of memory cells electrically connected in series between first and second select transistors and stacked above a semiconductor substrate;
a bit line, wherein a first end of the first select transistor is electrically connected to the bit line and a second end of first select transistor is electrically connected to the memory cells;
a source line, wherein a first end of the second select transistor is electrically connected to the source line and a second end of second select transistor is electrically connected to the memory cells;
a voltage generation circuit; and
a controller configured to control the voltage generation circuit to apply a write voltage to at least one the memory cells before a write operation is performed on the first and second select transistors and, during the write operation on the first and second select transistors, apply a first voltage to gates of the memory cells, a second voltage that is higher than the first voltage to gates of the first and second select transistors, and a ground voltage to the bit line and the source line.

10. The device according to claim 9, wherein the memory cells include a first group of memory cells that is electrically connected in series between the first select transistor and the semiconductor substrate and a second group of memory cells that is electrically connected in series between the second select transistor and the semiconductor substrate.

11. The device according to claim 10, further comprising:
a back gate transistor electrically connected between the first group of memory cells and the second group of memory cells.

12. The device according to claim 10, further comprising:
a plurality of word lines stacked above the semiconductor substrate;
a first semiconductor column extending through the word lines, the first group of memory cells being located at intersections of the first semiconductor column and the word lines; and
a second semiconductor column extending through the word lines, the second group of memory cells being located at intersections of the second semiconductor column and the word lines.

13. The device according to claim 12, further comprising:
first and second select signal lines stacked above the word lines at a same level above the word lines, wherein
the first semiconductor column extends through the first select signal line and the first select transistor is located at an intersection of the first select signal line and the first semiconductor column, and
the second semiconductor column extends through the second select signal line and the second select transistor is located at an intersection of the second select signal line and the second semiconductor column.

14. The device according to claim 9, wherein the first and second select transistors are located substantially the same distance away from the semiconductor substrate and have no other transistors or memory cells therebetween.

15. The device according to claim 9, wherein the first and second select transistors each include a charge storage layer.

16. A nonvolatile semiconductor memory device comprising:
a plurality of memory strings, each including memory cells electrically connected in series between first and second select transistors and stacked above a semiconductor substrate, wherein the first and second select transistors each include a charge storage layer and are adjacent to first and second select transistors of an adjacent memory string, respectively;
a voltage generation circuit; and
a controller configured to control the voltage generation circuit to, during the write operation on the first select transistor of a selected memory string, apply a first voltage to gates of the memory cells and a gate of the second select transistor of the selected memory string, a second voltage that is higher than the first voltage to gates of the first select transistors of non-selected memory strings, and a third voltage that is higher than the second voltage to a gate of the first select transistor of the selected memory string.

17. The device according to claim 16, further comprising:
a plurality of word lines stacked above the semiconductor substrate;
a first semiconductor column extending through the word lines, the memory cells of a first memory string being located at intersections of the first semiconductor column and the word lines; and
a second semiconductor column extending through the word lines, the memory cells of a second memory string being located at intersections of the second semiconductor column and the word lines.

18. The device according to claim 17, further comprising:
first select signal lines and second select signal lines between the word lines and the semiconductor substrate, wherein
the first and second semiconductor columns extend through the first select signal line and the first select transistors of the first and second memory strings are located at intersections of the first select signal line and the first and second semiconductor columns, and
the first and second semiconductor columns extend through the second select signal line and the second select transistors of the first and second memory strings are located at intersections of the second select signal line and the first and second semiconductor columns.

19. The device according to claim 16, further comprising:
a bit line, wherein a first end of the first select transistor is electrically connected to the bit line and a second end of first select transistor is electrically connected to the memory cells; and
a source line, wherein a first end of the second select transistor is electrically connected to the source line and a second end of second select transistor is electrically connected to the memory cells.

20. The device according to claim 19, wherein the bit line is set to the first voltage and the source line is set to positive voltage when writing to the first select transistor and the bit line is set to the first voltage and the source line is set to a ground voltage when writing to the second select transistor.
